(19) United States
(12) Patent Application Publication
(10) Pub. No.: US 2025/0271783 A1
(43) Pub. Date: Aug. 28, 2025

(54) METHOD FOR OPERATING AN OPTICAL SYSTEM, AND OPTICAL SYSTEM

(71) Applicant: Carl Zeiss SMT GmbH, Oberkochen (DE)

(72) Inventors: Alexander WIEGAND, Aalen (DE); Felix LANGE, Nattheim (DE); Maximilian SENDER, Boebingen a.d. Rems (DE); Aleksey SIDORENKO, Aalen (DE); Florian SCHAPPER, Neu-Ulm (DE); Marcel HAERTLING, Aalen (DE); Katja SCHICK, Aalen (DE)

(21) Appl. No.: 19/061,024

(22) Filed: Feb. 24, 2025

(30) Foreign Application Priority Data
Feb. 27, 2024 (DE) 10 2024 201 798.1

(51) Int. Cl. G03F 7/00; G02B 5/08

(52) U.S. Cl. CPC G03F 7/70958; G02B 5/0891; G03F 7/70233; G03F 7/70316

(57) ABSTRACT

A method for operating an optical system, such as in the FUV/VUV wavelength range, wherein the optical system comprises at least one reflective optical element having a metallic surface to which a metal fluoride layer is applied, and wherein the method includes irradiating the optical element with radiation, such as in the FUV/VUV wavelength range. In the method, the optical system is operated under oxidizing ambient conditions of the optical element during a first time interval, and under fluorinating ambient conditions of the optical element during a second time interval. The first time interval follows the second time interval, or the second time interval follows the first time interval. Optionally, the optical system is operated alternately under oxidizing ambient conditions of the optical element and under fluorinating ambient conditions of the optical element. The disclosure also relates to an optical system.

### CROSS-REFERENCE TO RELATED APPLICATIONS

This application claims benefit under 35 U.S.C. § 119 to German Application No. 10 2024 201 798.1, filed Feb. 27, 2024. The entire disclosure of this application is incorporated by reference herein.

### FIELD

The disclosure relates to a method for operating an optical system, such as in the FUV/VUV wavelength range, wherein the optical system comprises at least one reflective optical element having a metallic surface to which a metal fluoride layer is applied, and the method includes irradiating the optical element with radiation, in particular with radiation in the FUV/VUV wavelength range. The disclosure also relates to an optical system, for example for the FUV/VUV wavelength range, such as an FUV/VUV lithography apparatus or a wafer inspection system, which optical system comprises: a reflective optical element having a metallic surface to which a metal fluoride layer is applied; and a light source for irradiating the reflective optical element with radiation, for example in the FUV/VUV wavelength range.

Within the meaning of this application, the VUV wavelength range is understood to be a wavelength range between 100 nanometers (nm) and 200 nm (VUV wavelength range according to DIN 5031 Part 7). Within the meaning of this application, the FUV wavelength range is understood to be a wavelength range between 200 nm and 280 nm. The optical system described here can be designed or configured for operation for the VUV wavelength range, for operation for the FUV wavelength range or for operation in both wavelength ranges.

### BACKGROUND

In the VUV wavelength range, in particular, it is often not possible exclusively to employ transmissive optical elements, rather it is generally desirable to have recourse to reflective optical elements as well. Reflective optical elements having a metallic surface have proved worthwhile here, the surface often includes aluminium or containing aluminium since this material has a high reflectivity for the VUV wavelength range. It is possible for the metallic surface to be formed on a substrate of the optical element, including a metallic material. In general, the metallic surface is formed on a metal layer applied to a substrate of the optical element. The metal layer may have applied to it an overlying protective layer for protecting the metal layer against oxidation, which is usually a metal fluoride layer since metal fluorides have a large band gap.

Despite applying a protective layer in the form of a metal fluoride, it has been found that in an optical system operated with high radiation intensities such as occur in lithography and in particular during the inspection of masks and wafers, the reflective optical element is gradually degraded in tandem with a relatively high loss of reflectivity, which can shorten the lifetime of the reflective optical element. This is believed to be attributable to the fact that in such an optical system, the atmosphere surrounding the reflective optical element, which may be a vacuum or a purge gas, can unavoidably contain a residual concentration of oxygen-containing species, e.g. water or oxygen, which in combination with the high-energy photons can oxidize the surface of the protective metal fluoride layer. It is possible in principle, through suitable selection of the parameters in the surroundings of the reflective optical element, to significantly slow down oxidation or to passivate the metal fluoride layer (see below), although upon a relatively long period of operation significant losses of reflectivity nevertheless occur (e.g. 20% loss of reflectivity in the case of a layer of approximately 3 nm MgO on MgF₂, 15% in the case of a layer of approximately 3 nm Al₂O₃ on AlF₃), which typically cannot be accepted in view of the total transmission of the optical system.

DE 10 2018 211 499 A1 describes a reflective optical element configured as described above, wherein an oxide layer is additionally applied to the metal fluoride layer in order to protect the underlying layers and in this way to increase the lifetime of the reflective optical element. Applying an additional protective layer in the form of an oxide layer can entail the issue described above that most oxides have relatively high absorption at wavelengths of less than 160 nm and may therefore result in relatively large losses of reflectivity. DE 10 2018 211 499 A1 proposes reducing the loss of reflectivity by virtue of the fact that a standing wave of the electric field that forms during reflection has a minimum in the region of the oxide layer.

DE 10 2021 200 490 A1 describes a method for forming a protective layer on a reflective optical element which is configured as described further above. In order to form the protective layer, the metal fluoride layer is irradiated with electromagnetic radiation having at least one wavelength of less than 300 nm. The irradiation results in a passivation of the metal fluoride layer which counteracts degradation of the metal layer. The passivating protective layer is typically an oxide layer, which can lead to the issues described above.

U.S. Pat. No. 11,262,664 B2 describes a system and a method for protecting an optical element against damage during irradiation with VUV light. The system has a light source for generating VUV light and a chamber having a fluorine-based compound at a defined partial pressure. The optical element is arranged in the chamber and exposed to the fluorine-based compound. The VUV light generated by the light source has a sufficient energy to convert the fluorine-based compound in the chamber into a primary product which may contain atomic fluorine. In this way, the intention is to prevent a loss of fluorine and attendant oxidation of the optical element, which may include a metal fluoride, for example.

In the case of the method described in U.S. Pat. No. 11,262,664 B2, however, excess fluorine atoms adsorbed on the surface of the metal fluoride layer may diffuse and thereby reach the interface with the underlying metal layer and fluorinate the latter, which may likewise lead to a decreasing reflectivity of the optical element. An equilibrium between oxidizing and fluorinating species in the surroundings of the optical element could theoretically be found. In practice, however, this is not implementable or is possible only with relatively considerable outlay since each operating mode of the optical system (different wavelength bands, different intensity of the VUV radiation, . . . ) would involve a different concentration of fluorine-containing gases and each of these would be known and set exactly. As a consequence of this, the optical system described in U.S. Pat. No. 11,262,664 B2 might need to be operated with an excessively high concentration of fluorine-containing gases, which would likely accelerate the degradation of the optical element and thereby likely significantly reduce the transmission of the optical system.

### SUMMARY

The disclosure seeks to provide a method for operating an optical system, and an optical system, the transmission of which decreases only slightly even upon a long period of operation.

In accordance with one aspect, the disclosure provides a method of the type mentioned in the introduction, wherein the optical system is operated under oxidizing ambient conditions of the optical element during a first time interval and under fluorinating ambient conditions of the optical element during a second time interval, wherein the first time interval follows the second time interval, or the second time interval follows the first time interval.

The disclosure proposes operating the optical element in the optical system under oxidizing ambient conditions during a first time interval and under fluorinating ambient conditions during a second time interval. The inventors have discovered that during operation of the optical element under static ambient conditions, as is described for oxidizing ambient conditions in DE102021200490A1 and for fluoridating ambient conditions in U.S. Pat. No. 11,262,664 B2, during operation of the optical system harmful interactions can progress continuously as the period of operation of the optical system increases-believe to be by virtue of superficial oxidation of the metal fluoride layer under oxidic ambient conditions and by virtue of fluorination on the metallic surface or the interface with the metal layer under fluoridating ambient conditions.

The optical system can be operated alternately under oxidizing ambient conditions of the optical element and under fluorinating ambient conditions of the optical element. In this case, the reversible superficial oxidation of the metal fluoride layer can be limited by re-fluorination and at the same time too much addition of fluorine and thus irreversible fluorination of the interface between the metal fluoride layer and the metal layer or the metallic surface can be stopped. This exploits the fact that the oxidation and the re-fluorination of the surface of the metal fluoride layer are reversible, in contrast to the fluorination of the metallic surface that typically forms the interface between the metal layer and the metal fluoride layer.

In one variant, on a side of the metal fluoride layer facing away from the metallic surface, an oxidic layer has formed or an oxidic layer is formed under oxidizing ambient conditions of the optical element, wherein a thickness of the oxidic layer increases as the time duration of the oxidizing ambient conditions increases. The oxidic layer can be formed during irradiation of the surface of the metal fluoride layer, typically with radiation in the FUV/VUV wavelength range, under oxidizing ambient conditions, i.e. in the presence of an oxygen-containing gas in the surroundings of the reflective optical element. Formation of the oxidic layer involves a volume region of the metal fluoride layer near the surface being converted into the oxidic layer. The oxidic layer formed during the irradiation under oxidizing ambient conditions therefore does not extend over the entire thickness of the metal fluoride layer. For details of the parameters of the ambient atmosphere and the parameters of the irradiation which bring about or foster the formation of the oxidic layer, reference should be made to DE102021200490A1, which was cited in the introduction and the entirety of which is incorporated by reference into the content of this application. Alternatively, the—thin—oxidic layer can be applied to the metal fluoride layer as early as during production or the oxidic layer was formed under preceding oxidizing ambient conditions and was not completely ablated under fluorinating ambient conditions (see below).

In all cases described further above, the thickness of the oxidic layer on the metal fluoride layer can increase as the time duration of the oxidizing ambient conditions increases. The thin oxidic layer serves as a diffusion barrier and prevents fluorine atoms present in the surroundings from being able to reach the metallic surface or the interface between the metal layer and the metal fluoride layer. As the time duration of the fluorinating ambient conditions increases, the thickness of the thin oxidic layer on the surface of the metal fluoride layer decreases since, under fluorinating ambient conditions, this is wholly or partly converted into a fluoride again or re-fluorinated, as is described in greater detail below.

In one development, under the fluorinating ambient conditions of the optical element, the oxidic layer remains on the side of the metal fluoride layer facing away from the metallic surface. In this case, there is a switch from the fluorinating ambient conditions to the oxidic ambient conditions before the oxidic layer is completely ablated. In this way, the fluorination of the metallic surface or the interface between the metal fluoride layer and the metal layer can be stopped or at least greatly slowed down, which increases the lifetime of the reflective optical element by comparison with the method described in U.S. Pat. No. 11,262,664 B2. As a result of the optical system being operated under alternating ambient conditions of the reflective optical element, harmful but reversible reactions are restricted to the surface of the protective metal fluoride layer and irreparable depth damage owing to fluorination of the metallic surface or the interface between the metal fluoride layer and the metal layer is avoided.

In one development, the thickness of the metal fluoride layer is chosen in such a way that the electric field of a standing wave that forms when the reflective optical element is irradiated with radiation at a used wavelength of the optical system has a minimum in the region of the oxidic layer. In this variant, the thickness of the metal fluoride layer and also the thickness(es) of further layers which may be present and which are applied to the metallic surface are chosen such that the electric field or the amplitude thereof is minimized as much as possible in the oxidic layer, such that the absorption of the used radiation in the oxidic layer turns out to be as low as possible. For details of the design or suitable choice of the thickness of the metal fluoride layer and possibly of further layers which are applied to the metallic surface, e.g. in the form of adhesion promoter layers, reference should be made to DE102018211499A1, which was cited in the introduction and the entirety of which is incorporated by reference into the content of this application.

In a variant, in order to switch between oxidizing ambient conditions and fluorinating ambient conditions, a concentration of at least one fluorine-containing gas and/or of at least one oxygen-containing gas in the surroundings of the reflective optical element is changed, wherein the surroundings of the reflective optical element can be supplied with at least one fluorine-containing gas under fluorinating ambient conditions and with no fluorine-containing gas under oxidizing ambient conditions. For switching between oxidizing ambient conditions and fluorinating ambient conditions, it is typically sufficient to change the concentration or the metering of at least one fluorine-containing gas in the surroundings of the reflective optical element. In order to change the concentration, for example, the surroundings of the reflective optical element can be supplied with at least one fluorine-containing gas under fluorinating ambient conditions and with no fluorinating-containing gas under oxidizing ambient conditions. In general, it is not necessary for the surroundings of the optical element to be supplied with an oxidizing gas under oxidizing ambient conditions, since the residual concentrations of oxygen and/or water in the purge gas suffice to produce the oxidizing ambient conditions. The concentration of the oxidizing gas in the surroundings of the optical element can therefore be kept constant. However, it is also possible, in principle, alternatively or additionally to change the concentration of an oxygen-containing gas in the surroundings of the reflective optical element. The concentration of the fluorinating gas and/or of the oxidizing gas in the surroundings of the reflective optical element is chosen such that the surface of the optical element which forms the interface with the surroundings is oxidized under the oxidizing ambient conditions and is re-fluorinated under the fluorinating ambient conditions. Under the oxidizing ambient conditions, typically a thin oxidic layer arises or the thickness of an oxidic layer already present is increased, while under the fluorinating ambient conditions, the thin oxide layer can be converted into a fluoride again or its thickness is reduced, and under fluorinating ambient conditions as well a residual thickness of the oxidic layer may remain on the metal fluoride layer (see above).

In one development, the concentration of the at least one fluorine-containing gas and/or of the at least one oxygen-containing gas in the surroundings of the optical element is controlled as a function of at least one control parameter which forms a measure of the reflectivity of the reflective optical element. The concentration of the at least one fluorine-containing gas and/or of the at least one oxygen-containing gas and thus the time of switching between the fluorinating and the oxidizing ambient conditions can be controlled as a function of at least one control parameter based on a measurement variable which represents a measure of the reflectivity of the optical element. The control can help enable automated reaction to different operating modes of the optical system, e.g. a variation of the electromagnetic spectrum of the used radiation, the intensity of the used radiation, etc. In the case of the method described in U.S. Pat. No. 11,262,664 B2, in contrast, either it is desirable to know the ideal concentration of the fluorine-containing gas depending on the operating mode of the optical system or too much fluorine-containing gas is metered in, which has the consequence that the lifetime of the reflective optical element decreases.

In one development, the concentration of the at least one fluorine-containing gas and/or of the at least one oxygen-containing gas is kept constant if the control parameter is between a first, lower threshold value and a second, upper threshold value. As has been described above, the control parameter or a variable derived therefrom forms a measure of the reflectivity of the optical element. For the case where the optical system has a total transmission or the optical element has a reflectivity which is between an upper and a lower threshold value, the concentration of the fluorine-containing gas and/or of the oxygen-containing gas can be kept constant, i.e. there is no need to switch between fluorinating and oxidizing ambient conditions. The lower threshold value can be for example of the order of magnitude of approximately 95% of the transmission of the optical system or the reflectivity of the optical element, and the upper threshold value approximately 99%. Of course, other values are also possible depending on the optical system or the control parameter.

In one development, the concentration of the fluorine-containing gas is increased and/or the concentration of the oxygen-containing gas is reduced if the control parameter falls below the first threshold value, and/or the concentration of the fluorine-containing gas is reduced and/or the concentration of the oxygen-containing gas is increased if the control parameter exceeds the second threshold value. If the first, lower threshold value is undershot, the thickness of the oxidic layer is too large, which results in a reduction of the transmission of the optical system. By reducing the concentration of the oxygen-containing gas and/or increasing the concentration of the fluorine-containing gas, it is possible to increase the transmission of the optical system. Accordingly, if the second threshold value is exceeded, the thickness of the oxidic layer is so small that there is a threat of degradation of the metallic surface or the interface between the metal layer and the metal fluoride layer. That can be combated by reducing the concentration or the partial pressure of the fluorine-containing gas and/or by increasing the concentration or the partial pressure of the oxygen-containing gas.

Optionally, after the concentration of the at least one fluorine-containing gas and/or of the at least one oxygen-containing gas has been changed, the optical system is operated under constant ambient conditions at least for a predefined hold time. It can be desirable to not to let the control loop progress permanently, but rather to set or predefine a hold time in which the optical system is operated with constant ambient conditions after the ambient conditions have been switched or changed. The hold time is typically of the order of magnitude of hours or days. It goes without saying that even after the hold time has elapsed, the ambient conditions are not changed automatically, but rather as a function of the value of the control parameter. The hold time can be set for example as a function of the concentration of the fluoridic gas such that a thin oxide layer always remains as a diffusion barrier for the fluorine atoms.

In one development, the control parameter is selected from the group comprising: total transmission of the optical system, reflectivity of the reflective optical element, chemical composition of the surface of the optical element, temperature of the optical element. The at least one control parameter is measured with the aid of a suitable measuring system. For the measurement of the total transmission of the optical system, the measuring system can be arranged as an additional component outside a chamber into which the reflective optical element is introduced during operation of the optical system. For the measurement of the reflectivity of the optical element, the latter can optionally be irradiated with the light from a measurement light source e.g. in the VUV wavelength range and the light reflected from the optical element can be detected by a detector. This can exploit the fact that oxides are highly absorbent in the VUV wavelength range, while fluorides are generally transparent. For the measurement of the temperature, a temperature sensor can be used, for example in the form of a thermocouple integrated in a mirror holder, a pyrometer or the like. The temperature is a measure of the absorption of the reflective optical element and thus of the degree of oxidation of the reflective optical element or the reflectivity thereof.

Alternatively or additionally, it is possible to measure a chemical composition of a surface or of a volume region near the surface of the optical element and thus the chemical composition or the stoichiometry of the reflective optical element or of the metal fluoride layer. Measurement methods known to a person skilled in the art, e.g. XPS, i.e. x-ray photoelectron spectroscopy, XRF, i.e. x-ray fluorescence spectroscopy, etc., can be used for this purpose. In this case, the chemical composition or a measure of the chemical composition, e.g. a concentration of fluorine and/or oxygen on the surface which forms the interface with the surroundings of the optical element, can be used as control parameter. It goes without saying that it is also possible to combine the control parameters described here and further control parameters in the control of the optical system.

In an aspect, the disclosure provides an optical system of the type mentioned in the introduction which is configured for operation under oxidizing ambient conditions of the optical element during a first time interval and under fluorinating ambient conditions of the optical element during a second time interval, wherein the first time interval follows the second time interval, or the second time interval follows the first time interval. Optionally, the optical system is configured for operation under alternately oxidizing ambient conditions of the optical element and under fluorinating ambient conditions of the optical element. The optical system can have features described above in connection with the method.

In one embodiment, the reflective optical element is arranged in a chamber and the optical system has a supply device for supplying at least one fluorine-containing gas and/or at least one oxygen-containing gas into the chamber, wherein the supply device is configured for setting a concentration of the fluorine-containing gas and/or a concentration of the oxygen-containing gas in the chamber.

As fluorinating agent or as fluorine-containing gas, for example, it is possible to use the following fluorine-containing gases: F₂, HF, XeF₂, NF₃, CF₄, SF₆. During operation under fluorinating ambient conditions, the partial pressure of the fluorinating agent is typically between 10⁻⁹ mbar and 10⁻¹ mbar or between 1 pptV and 100 ppmV in the purge gas, in particular between 10⁻⁶ mbar and 10⁻³ mbar or between 1 ppbV and 1 ppmV in the purge gas. For example, the fluorine-containing gas can be set to the desired partial pressure by way of a needle valve and can be measured or controlled by way of a dedicated fluorine gas sensor (e.g. a residual gas analyser). As has been described further above, the concentration of the at least one oxygen-containing gas can be kept constant or can be changed in a manner corresponding to the setting of the concentration of the fluorine-containing gas. For this purpose, the optical system can have a metering unit for the oxygen-containing gas or the oxidizing species such as e.g. H₂O or O₂. Moreover, a corresponding sensor for determining the partial pressure or the concentration of the oxidizing species or of the oxygen-containing gas can be integrated in the optical system.

The light source for irradiating the reflective optical element is typically the used light source of the optical system, the wavelength or the wavelength range of which is typically in the FUV/VUV wavelength range. In order to set the fluorinating ambient conditions, the light source typically fulfils two tasks:

The light source is intended to bring about photodissociation of the at least one fluorine-containing gas in order to provide fluorine atoms for the fluorination of the oxidic layer. The wavelength range of the light source can be adapted to the absorption cross section of the fluorine-containing gas in order to make fluorine atoms available as efficiently as possible. For this purpose, the light source used can make available e.g. light in the wavelength range of between 115 nm and 1000 nm, such as between 120 nm and 170 nm, for example between 140 nm and 170 nm.

The light source also has to provide the activation energy for the fluorination process. The wavelength of the light provided by the light source can be suitably adapted or predefined for this purpose. For this purpose, the light source used should generate light in the wavelength range of 115 nm to 1000 nm, such as between 120 nm and 200 nm, for example between 140 nm and 200 nm.

Alternatively or additionally, the photodissociation of the fluorine-containing gas and/or the activation energy can be implemented by increasing the temperature or in some other way, for example by using a plasma. By way of example, it is known to carry out plasma-induced cleaning of PECVD coating apparatuses using NF₃.

In a further embodiment, the optical system comprises a control device for controlling the concentration of the at least one fluorine-containing gas and/or of the at least one oxygen-containing gas in the surroundings of the optical element as a function of at least one control parameter which forms a measure of the reflectivity of the reflective optical element, and at least one measuring device for measuring the at least one control parameter. As has been described further above in connection with the method, it is desirable to control the concentration of the fluorine-containing or oxygen-containing gas or the time of switching between oxidizing ambient conditions and fluoridating ambient conditions. For this purpose, a metering unit of the fluorine-containing gas can be coupled to the measuring device of the control parameter via a feedback loop, such that the desired concentration of the fluorine-containing gas and/or of the oxygen-containing gas is set automatically. For this purpose, the control device can have a mass flow controller, for example.

In one development, the at least one control parameter is selected from the group comprising: total transmission of the optical system, reflectivity of the reflective optical element, chemical composition of the surface of the optical element, temperature of the optical element. As has been described above in connection with the method, the control parameter can be measured with the aid of a suitable measuring device or with the aid of a suitable sensor. The sensor or the measuring device can be integrated in the chamber in which the reflective optical element is arranged. However, it is also possible for the measuring device to be arranged outside the chamber or the housing, for example if the total transmission of the optical system is measured as control parameter.

The housing or the chamber in which the reflective optical element is arranged, and all further components which come into contact with the fluorine-containing gas (e.g. NF₃, XeF₂, SF₆, CF₄, HF, F₂), the photodissociated species thereof (e.g. F, F₂, F*) and/or the conversion products thereof (e.g. HF) are desirably resistant to these species. Resistant means that a passivating layer forms e.g. on the inner side of the chamber. As materials, for example, the following materials and alloys thereof are usable: Ni, Fe, Cu, Co, Sc, Y and Hf. One example of such a material is Monel metal, which is an alloy of Ni, Cu and Fe. For example, it is desirable for there to be no formation of volatile fluorine compounds that are precipitated on the reflective optical element or on other optical units. Accordingly, it is desirable for the metals used to be free of Cr or Ti. Alternatively, the inner side of the chamber or the chamber wall can be provided with a fluorine-resistant coating in order to prevent corrosion. Such a coating can be applied e.g. in a galvanic process. Possible coating materials are for example NiP, Pt or mixtures of Ru/Rh.

In an embodiment, the chamber has an entrance window for light from the light source to enter into the chamber and/or an exit window for light from the light source to exit from the chamber. The entrance and/or exit window can be used to separate the surroundings of the reflective optical element with the fluorine-containing and/or oxygen-containing gases from the rest of the optical system. In principle, the chamber can also include the entire optical system, to put it more precisely all the optical components of the optical system, if separation of the ambient conditions is not necessary or if the components are resistant to fluorine or to fluorine species.

The metal fluoride layer of the reflective optical element can comprise at least one material selected from the group comprising: magnesium fluoride, aluminium fluoride, sodium fluoride, lithium fluoride, chiolite, cryolite, erbium fluoride, neodymium fluoride, gadolinium fluoride, dysprosium fluoride, samarium fluoride, holmium fluoride, hafnium fluoride, lanthanum fluoride, europium fluoride, lutetium fluoride, cerium fluoride, barium fluoride, yttrium fluoride.

The metallic surface of the reflective optical element can be formed on a metal layer comprising at least one material selected from the group comprising: aluminium, rhodium, ruthenium, palladium, osmium, iridium, platinum, magnesium, germanium or a combination thereof.

The optical system operated with alternating oxidizing and fluorinating ambient conditions which has been described further above makes it possible to exchange the reflective optical element, which is typically a mirror, with a reduced frequency and thereby makes it possible to increase the period of operation of the optical system with at the same time low costs.

Further features of the disclosure are evident from the following description of exemplary embodiments of the disclosure, with reference to the figures of the drawing, which show certain details of the disclosure, and from the claims. The individual features can each be realized individually by themselves or as a plurality in any desired combination in a variant of the disclosure.

### BRIEF DESCRIPTION OF THE DRAWINGS

Exemplary embodiments are illustrated in the schematic drawings and are explained in the following description. In the figures:

FIG. 1A shows a schematic illustration of the irradiation of a reflective optical element under oxidizing ambient conditions;

FIG. 1B shows a schematic illustration of the irradiation of a reflective optical element under fluorinating ambient conditions;

FIG. 1C shows a schematic illustration of the irradiation of a reflective optical element under alternately oxidizing and fluorinating ambient conditions;

FIG. 2A shows a schematic illustration of a control circuit for controlling alternately oxidizing or fluorinating ambient conditions;

FIG. 2B shows a schematic illustration of the total transmission of the optical system as a function of time;

FIG. 3 shows a schematic illustration of an optical system having a reflective optical element which is configured for controlling alternately oxidizing and fluorinating conditions in the surroundings of the reflective optical element;

FIG. 4 shows a schematic illustration of an optical system for the VUV wavelength range in the form of a VUV lithography apparatus; and

FIG. 5 shows a schematic illustration of an optical system for the VUV wavelength range in the form of a wafer inspection system.

### DETAILED DESCRIPTION

In the following description of the drawings, identical reference signs are used for identical or functionally identical components.

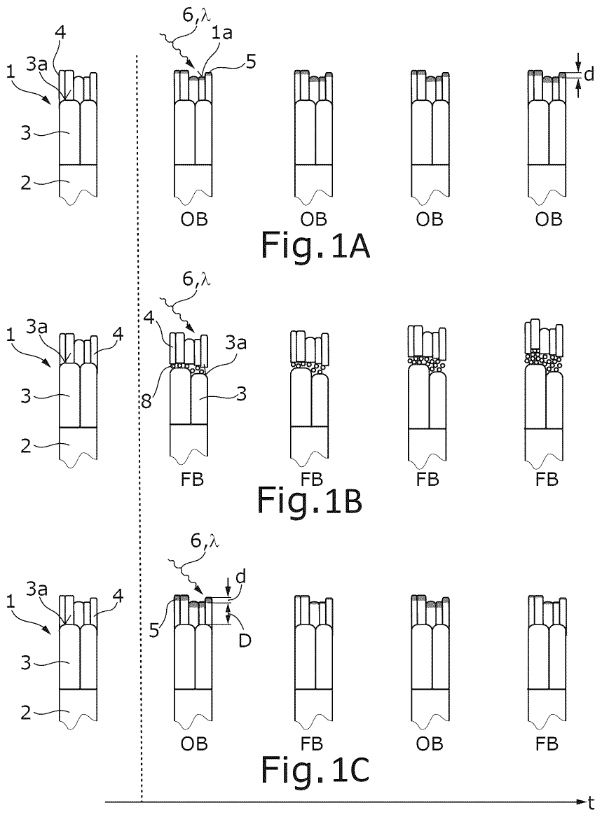

FIGS. 1A-1C show highly schematically a detail of a reflective optical element 1 in the form of a mirror. The reflective optical element 1 has a substrate 2, on which is formed a metal layer 3 having a metallic surface 3a situated on a side facing away from the substrate 2. In the example shown, the substrate 2 includes silicon, but it goes without saying that the substrate 2 can also be formed from some other metallic or non-metallic material, e.g. from a glass ceramic, a ceramic, etc.

The metal fluoride layer 4 is applied in a conventional coating method (by evaporation). The metal fluoride layer 4 serves to protect the underlying metal layer 3 against oxidation. In the example shown, the material of the metal layer 3 is aluminium, and the material of the metal fluoride layer 4 is magnesium fluoride (MgF₂), but other materials can also be used.

It has been found that the presence of the metal fluoride layer 4 alone is not sufficient to protect the optical element 1 against degradation if the reflective optical element 1 is irradiated with high powers or irradiances during operation of an optical system that is not illustrated pictorially in FIGS. 1A-1C. Despite the presence of the metal fluoride layer 4, the Al material of the metal layer 3 is oxidized to form Al₂O₃ in a comparatively short time period of several hours or days, which results in a significant reduction of the reflectivity of the reflective optical element 1. If the loss of reflectivity is too great, it is desirable for the reflective optical element 1 to be exchanged.

In order to increase the lifetime of the reflective optical element 1, a thin passivating oxidic layer 5 can be applied to the reflective optical element 1, as is illustrated in FIG. 1A. For this purpose, the reflective optical element 1 is irradiated with radiation 6 at at least one wavelength λ of less than 300 nm, typically of less than 200 nm. The irradiation can take place in particular at one or a plurality of wavelengths λ that are between 115 nm and 200 nm. The irradiation takes place under oxidizing ambient conditions OB, i.e. in surroundings in which there is at least one oxygen-containing gas with a sufficient concentration.

Formation of the oxidic layer 5 involves a volume region of the metal fluoride layer 4 near the surface being converted into the oxidic layer 5. The oxidic layer 5 formed during the irradiation under oxidizing ambient conditions OB therefore does not extend over the entire thickness of the metal fluoride layer 4. In the example shown where the material of the metal fluoride layer is MgF₂, the oxidic layer 5 includes MgO. For details of the oxidizing ambient conditions OB which are desirable for the formation of the thin oxidic layer 5, reference should be made to DE102021200490A1. As can be discerned in FIG. 1A, the thickness d of the oxidic layer 5 increases as the time duration increases during which the reflective optical element 1 is exposed to the oxidic ambient conditions OB.

FIG. 1B shows the optical element 1 from FIG. 1A under fluorinating ambient conditions FB. The fluorinating ambient conditions FB are intended to prevent the formation of an oxidic layer on the metal fluoride layer 4 that contributes to the reduction of the reflectivity of the reflective optical element 1 (see above). The fluorinating ambient conditions can be realized for example in the manner described in U.S. Pat. No. 11,262,664 B2.

During operation of the reflective optical element 1 under fluorinating ambient conditions FB, fluorine atoms 8 may diffuse to the metallic surface 3a, which has the consequence that a thin intermediate layer of AlF₃ forms between the metal layer 3 and the metal fluoride layer 4, the intermediate layer becoming thicker as the time duration of the fluorinating ambient conditions FB increases, which likewise leads to a decrease in the reflectivity of the reflective optical element 1.

FIG. 1C shows the reflective optical element 1 operated alternately under oxidizing ambient conditions OB and under fluorinating ambient conditions FB. As can be discerned in FIG. 1C, the thickness d of the oxidic layer 5 increases under oxidizing ambient conditions OB and decreases under fluorinating ambient conditions FB. Given a suitable choice of the times of switching between oxidizing ambient conditions OB and fluorinating ambient conditions FB, a thin oxidic layer 5 may permanently remain on the metal fluoride layer 4, i.e. the oxidic layer 5 which is or has been formed under oxidizing ambient conditions OB of the reflective optical element 1 or which has already been applied to the metal fluoride layer 4 during production of the reflective optical element 1 remains on the side of the metal fluoride layer 4 facing away from the metallic surface 3a under the fluorinating ambient conditions FB as well. Since the oxidic ambient conditions OB do not permanently persist, growth of the oxidic layer 5 to an excessively large thickness d can be prevented, i.e. the thickness d of the oxidic layer 5 can be limited in order to prevent or limit a decrease in the reflectivity of the optical element 1.

In order to minimize the decrease in the reflectivity of the optical element, it is desirable for the thickness D of the metal fluoride layer 4 to be chosen in such a way that the electric field of a standing wave that forms when the reflective optical element 1 is irradiated with radiation 6 at a used wavelength λ has a minimum in the region of the oxidic layer 5. This can be achieved for example in the manner described in DE102018211499A1.

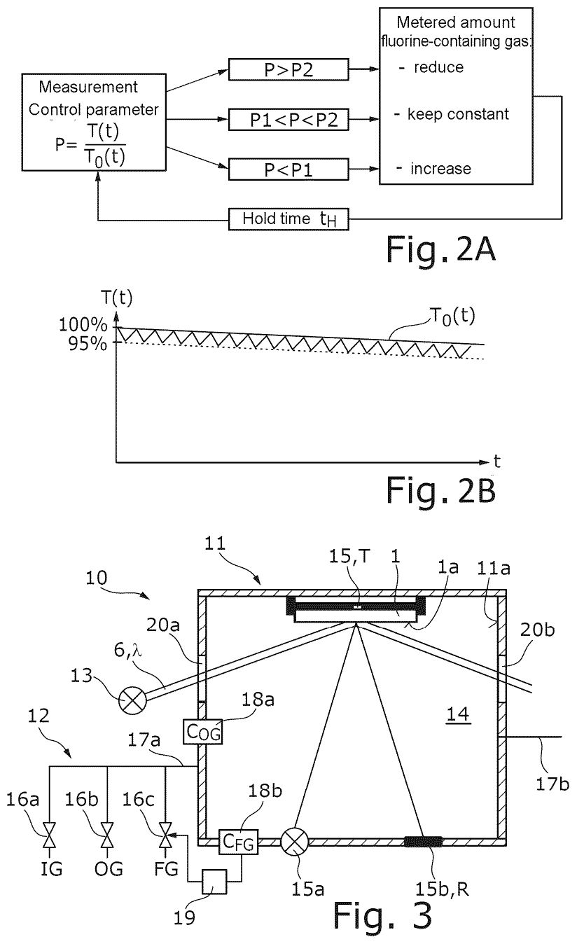

It is desirable to control a respective time of switching between the oxidizing ambient conditions OB and the fluorinating ambient conditions FB. Such control or such a control process can take place for example in the manner described below in association with FIGS. 2A, 2B on an optical system 10 which is illustrated in FIG. 3 and which is described in greater detail further below.

The optical system 10 illustrated in FIG. 3 comprises a chamber 11, in which the reflective optical element 1 from FIG. 1C is arranged, a supply device 12 and an FUV/VUV radiation source 13. The reflective optical element 1 is arranged in an interior of the chamber 11, the interior forming surroundings 14 of the reflective optical element 1. The reflective optical element 1 is mounted on an optical unit mount, in which is embedded a measuring device in the form of a temperature sensor 15, which serves to measure the temperature T of the reflective optical element 1.

In the example shown, the supply device 12 serves to supply protective gas in the form of inert gas IG, to supply at least one oxygen-containing reactive gas OG and to supply at least one fluorine-containing reactive gas FG into the chamber 11. The supply device 12 comprises a first valve 16a for the controlled supply of the inert gas IG, a second valve 16b for the controlled supply of the at least one oxygen-containing gas OG, and a third valve 16c for the controlled supply of the at least one fluorine-containing gas FG. The second valve 16b and the third valve 16c are in each case a controllable metering valve.

The optical system 10 additionally comprises a gas inlet 17a into the chamber 11 in the region of the supply device 12 and also a gas outlet 17b.

In the example illustrated, the inert gas IR is argon, but it is also possible to use other inert gases IR, for example other light noble gases such as helium or neon. Mixtures of noble gases, in particular of the noble gases mentioned, can also be used as inert gas IR. As oxygen-containing gas, it is possible to use for example water H₂O or molecular oxygen O₂. As fluorine-containing gas, it is possible to use for example the following gases: F₂, HF, XeF₂, NF₃, CF₄, SF₆.

The FUV/VUV radiation source 13 serves for irradiating the reflective optical element 1, to put it more precisely the surface 1a thereof, with FUV/VUV radiation 6. The radiation 6 thus has a used wavelength λ in the FUV/VUV wavelength range. By way of example, in the example illustrated, the FUV/VUV radiation 6 enters the chamber 11 through an entrance window 20a composed of MgF₂ and exits from the chamber 11 via an exit window 20b composed of MgF₂. The chamber 11 is gas-tightly sealed by the two windows 20a,b.

An inner side 11a of the chamber 11 is resistant to the fluorine-containing gas FG and the conversion products thereof. For this purpose, in the example illustrated, the chamber 11, at least on its inner side 11a, is formed from a metal in the form of Monel steel, which forms a passivating layer in order to prevent corrosion. In principle, the chamber 11 can also be formed from other corrosion-resistant metals if the latter are free of Cr and Ti. Alternatively, a corrosion-resistant coating, e.g. composed of NiP, Pt or Ru/Rh mixtures, can be applied to the inner side 11a of the chamber 11. The corrosion-resistant coating can be applied to the inner side 11a of the chamber 11 using a galvanic process, for example. The components which are arranged in the chamber 11 and which come into contact with the fluorine-containing gas FG are likewise resistant to the fluorine-containing gas FG and the conversion products thereof.

Furthermore, the optical system 10 comprises by way of example a first sensor 18a for measuring the concentration c_{OG} of the oxygen-containing gas OG in the chamber 11 and also a second sensor 18b for measuring the concentration c_{FG} of the fluorine-containing gas FG in the chamber 61. It is possible for the respective sensor 18a, 18b to be configured for measuring the concentration of different oxygen-containing or fluorine-containing gases in the chamber 11. By way of example, the first sensor 18a can be configured for measuring the concentration c_{OG} or the partial pressure of water H₂O and of oxygen O₂ in the chamber 11.

The optical system 10 also has a control device 19 for controlling the partial pressure or the concentration c_{FG} of the fluorine-containing gas FG in the chamber 11 to a target value, the control being effected by an actual measurement value of the second sensor 18b for measuring the concentration c_{FG} of the fluorine-containing gas FG in the chamber 11 and by the control of the third valve 16c. The second sensor 18b can be configured only for measuring the partial pressure c_{FW} of the fluorine-containing gas FG, but a residual gas analyser is also a possibility, which can also determine the partial pressures or the concentrations of other gases contained in the chamber 11. It is possible for such a residual gas analyser to perform the function of both the sensors 18a,b illustrated in FIG. 3. For the case where the third valve 16c is a metering valve, for example a mass flow controller, it is possible optionally to dispense with the use of the second sensor 18b for measuring the concentration c_{FG} of the fluorine-containing gas FG in the chamber 11.

The control device 19 also serves for switching or changing over between the oxidizing ambient conditions OB described in association with FIG. 1C and the fluorinating ambient conditions FB in the chamber 11 or in the surroundings 14 of the reflective optical element 1, which takes place as a function of at least one control parameter which is a measure of the reflectivity R of the optical element 1.

The control parameter can be for example the total transmission T(t) of the optical system 10 or a control variable derived therefrom. The total transmission T(t) of the optical system 10 at a time t, as shown in FIG. 2B, is defined as the quotient between the light intensity I_{transmitted}(t) measured at the output of the optical system 10 and the light intensity I_{light source}(t) generated by the light source 13 at the time t: T(t)=I_{transmitted}(t)/I_{light source}(t). The respective light intensities and thus the total transmission T(t) can be determined with the aid of measuring devices that are not illustrated pictorially, e.g. in the form of optical sensors.

As control parameter P for the control of operation of the optical system 10, use is made of the quotient of the measured total transmission T(t) at the time t and a total transmission T₀(t) attributable to long-term changes in the optical system 10 which are not attributable to changes in the reflectivity R of the reflective optical element 1. A prerequisite for the use of the control parameter P is that comparatively short-term changes or fluctuations in the total transmission T(t) of the optical system 10 on an hourly or daily basis are attributable to changes in the reflectivity R of the reflective optical element 1, while long-term changes caused e.g. by other optical components are known or can be computed for the control. As a consequence, the total transmission T(t) decreasing over time or the control parameter P is a direct measure of the oxidation of the surface 1a or of the reflectivity R of the reflective optical element 1.

In the example shown, three cases are distinguished for the control, as is illustrated in FIG. 2A: In the first case, the total transmission or the control parameter P is small and lies below a lower threshold value P1, which can be approximately 95%, for example. In this case, the concentration c_{FG} of the fluorine-containing gas FG is increased in order to reverse the superficial oxidation of the reflective optical element 1 or in order to re-fluorinate the latter and to increase the total transmission of the optical system 10 or the control parameter P. In principle, it is possible here also to reduce the concentration c_{OG} of the oxidizing gas(es) OG in the chamber 11, but this is not absolutely necessary.

In the second case, in which the control parameter P lies between the first, lower threshold value P1 and a second, upper threshold value P2, which can be e.g. approximately 99%, the concentration c_{FG} of the fluorine-containing gas FG is kept constant.

In the third case, in which the control parameter P exceeds the second threshold value P2, the oxidic layer 5 is almost completely fluorinated. Therefore, the metering or the concentration c_{FG} of the fluorine-containing gas FG is controlled downwards, such that oxidizing conditions are present again. In this case, in particular, the concentration c_{OG} of oxidizing gases OG in the chamber 11 can be increased in order to accelerate the oxidation process.

As can likewise be discerned in FIG. 2A, the control loop in the control device 19 does not progress permanently, rather after the concentration c_{FG}, c_{OG} of the at least one fluorine-containing gas FG and/or of the at least one oxygen-containing gas OG has been changed upon the respective threshold value P1, P2 being undershot or exceeded, the optical system 10 is operated under constant ambient conditions at least for a predefined hold time ty before a check is once again made to ascertain whether it is desirable to switch between the oxidizing ambient conditions OB and the fluorinating ambient conditions FB. The hold time t_{H} is typically of the order of magnitude of a plurality of hours or days.

As an alternative or in addition to the control by way of the total transmission or the control parameter P, the control of the time of switching between the oxidizing ambient conditions OB and the fluorinating ambient conditions FB can be effected by the control device 19 with the aid of other control parameters determined with the aid of suitable measuring devices. By way of example, the reflectivity R of the reflective optical element 1 can be measured with the aid of a measuring device 15a, 15b having a VUV measurement light source 15a for irradiating the reflective optical element 1 with measurement light and a detector 15b for detecting the measurement light reflected from the optical element 1. In addition or as an alternative to the reflectivity R of the optical element 1, the absorption of the optical element 1 can also be determined by the temperature T of the optical element 1 being measured with the aid of the temperature sensor 15 described further above. The chemical composition of the surface 1a of the reflective optical element 1 can also be determined with the aid of suitable measuring devices or measuring methods, e.g. using XPS or XRF. For the control of the ambient conditions OB, FB of the optical element 1, one of the control parameters P, R, T, etc., can be measured, but it is also possible to carry out the control on the basis of two or more of the control parameters P, R, T, etc. The control device 19 can be configured in the form of suitable hardware and/or software and is connected to the respective measuring devices 15, 15a,b via electrical lines.

The concentration c_{FG} of the fluorine-containing gas FG in the chamber 11 at which fluorinating ambient conditions FB are present in the surroundings 14 of the optical element 1 depends on the type of fluorine-containing gas FG. During operation of the chamber 11 in a vacuum, i.e. without an inert gas IG, the partial pressure or the concentration c_{FG} of the fluorine-containing gas FG is typically between 10⁻⁹ mbar and 10⁻¹ mbar, in particular between 10⁻⁶ mbar and 10⁻³ mbar. During operation of the chamber 11 using the purge or inert gas IG, the concentration c_{FG} is typically between 1 pptV and 100 ppmV, in particular between 1 ppbV and 1 ppmV, in the purge or inert gas IG.

The light source 13 generates light in the FUV/VUV wavelength range which both brings about the photodissociation of the fluorine-containing gas FG to form fluorine species e.g. in the form of atomic fluorine F or fluorine radicals and provides the activation energy used for converting the oxide of the oxidic layer 5 into a fluoride.

Under oxidizing ambient conditions OG, the concentration c_{FG} of the fluorine-containing gas FG is below the values specified above, and is typically zero, i.e. no fluorine-containing gas FG is supplied to the surroundings 14 or the chamber 11 under oxidizing ambient conditions OG. The concentration c_{OG} of oxygen-containing gas in the form of oxygen O₂ is generally between approximately 1 pptV and 100 ppmV. The concentration c_{OG} of water as oxygen-containing gas OG in the chamber 11 should be low and should typically not exceed a value of approximately 100 ppbV. The residual gas concentrations of oxygen O₂ and of water in the chamber 11 if a purge gas is present may be sufficient to produce the oxidizing ambient conditions OG. In this case, it is not necessary for the chamber 11 to be additionally supplied with an oxygen-containing gas in order to establish the oxidizing ambient conditions OG.

In the case of the optical system 10 in FIG. 3, by way of example, the chamber 11 is separated from the rest of the components of the optical system 10 by the windows 20a,b, but this is not absolutely necessary. The chamber 11 can also include all the optical components of the optical system 10, provided that they are resistant to the fluorine-containing gas FG or the reaction products thereof. The optical system 10 in FIG. 3 can be configured in various ways. Two examples of such an optical system 10 are described below.

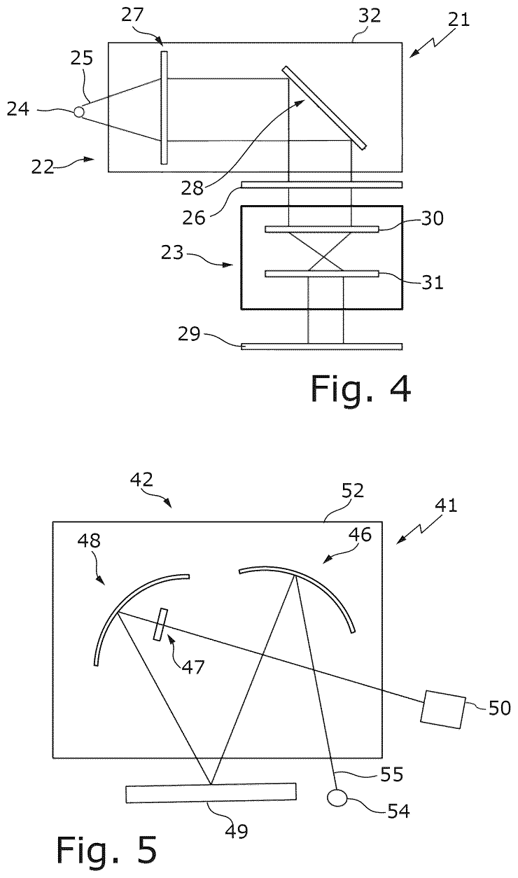

FIG. 4 shows an optical system for the VUV wavelength range in the form of a VUV lithography apparatus 21. The VUV lithography apparatus 21 comprises two optical arrangements, namely an illumination system 22 and a projection system 23. The VUV lithography apparatus 21 additionally has a light source 24, which can be an excimer laser, for example.

The radiation 25 emitted by the light source 24 is conditioned with the aid of the illumination system 22 such that a mask 26, also called a reticle, is illuminated thereby. In the example shown, the illumination system 22 has a housing 32, in which there are disposed both transmissive and reflective optical elements. In a representative manner, the illustration shows a transmissive optical element 27, which focuses the radiation 25, and a reflective optical element 28, which deflects the radiation.

The mask 26 has, on its surface, a structure which is transferred to an optical element 29 to be exposed, for example a wafer, with the aid of the projection system 23 for the purpose of producing semiconductor components. In the example shown, the mask 26 is configured as a transmissive optical element. In alternative embodiments, the mask 26 can also be configured as a reflective optical element.

The projection system 22 has at least one transmissive optical element in the example illustrated. The example shown illustrates, in a representative manner, two transmissive optical elements 30, 31, which serve, for example, to reduce the structures on the mask 26 to the size desired for the exposure of the wafer 29.

Both in the illumination system 22 and in the projection system 23, a wide variety of transmissive, reflective or other optical elements can be combined with one another as desired, including in a more complex manner. Optical arrangements without transmissive optical elements can also be used for VUV lithography.

FIG. 5 shows an optical system for the VUV wavelength range in the form of a wafer inspection system 41, but a mask inspection system can also be involved. The wafer inspection system 41 has an optical arrangement 42 with a light source 54, the radiation 55 from which is directed onto a wafer 49 via the optical arrangement 42. For this purpose, the radiation 55 is reflected onto the wafer 49 by a concave mirror 46. In the case of a mask inspection system, it would be possible to replace the wafer 49 with a mask to be examined. The radiation reflected, diffracted and/or refracted by the wafer 49 is directed onto a detector 50 for further evaluation by a further concave mirror 48, which is likewise associated with the optical arrangement 42, via a transmissive optical element 47. The wafer inspection system 41 additionally has a housing 52, in which there are disposed the two mirrors 46, 48 and the transmissive optical element 47. By way of example, the light source 54 can be exactly one light source or a combination of a plurality of individual light sources in order to provide a substantially continuous radiation spectrum. In modifications, it is also possible to use one or more narrowband light sources 54.

The VUV lithography apparatus 21 shown in FIG. 4 and the wafer inspection system 41 shown in FIG. 5 are configured for operation under alternately oxidizing ambient conditions OB and fluorinating ambient conditions FB of the respective mirrors 28 and 46, 48.

What is claimed is:

1. A method of operating an optical system comprising a reflective optical element which comprises a metallic surface supporting a metal fluoride layer, the method comprising:
irradiating the optical element with radiation,
wherein:
the optical system is operated under oxidizing ambient conditions of the optical element during a first time interval;
the optical system is operated under fluorinating ambient conditions of the optical element during a second time interval; and
the first time interval follows the second time interval, or the second time interval follows the first time interval.

2. The method of claim 1, wherein the radiation is in the FUV/VUV wavelength range.

3. The method of claim 1, wherein the optical system is operated alternately under oxidizing ambient conditions of the optical element and under fluorinating ambient conditions of the optical element.

4. The method of claim 1, wherein:
on a side of the metal fluoride layer facing away from the metallic surface, an oxidic layer has formed or is formed under oxidizing ambient conditions of the optical element; and
a thickness of the oxidic layer increases as the time duration of the oxidizing ambient conditions increases.

5. The method of claim 4, wherein, under the fluorinating ambient conditions of the optical element, the oxidic layer remains on the side of the metal fluoride layer facing away from the metallic surface.

6. The method of claim 4, wherein:
the reflective optical element is configured so that a standing wave forms when the reflective optical element is irradiated with radiation at a used wavelength of the optical system; and
the standing wave has a minimum in the region of the oxidic layer.

7. The method of claim 1, further comprising, to switch between oxidizing ambient conditions and fluorinating ambient conditions, changing a concentration of a fluorine-containing gas and/or a concentration of an oxygen-containing gas in the surroundings of the reflective optical element.

8. The method of claim 7, wherein changing the concentration comprises supplying the surroundings of the reflective optical element with a fluorine-containing gas under fluorinating ambient conditions and with no fluorine-containing gas under oxidizing ambient conditions.

9. The method of claim 7, further comprising controlling the concentration of the fluorine-containing gas and/or of the concentration of the oxygen-containing gas in the surroundings of the optical element as a function of a control parameter which forms a measure of a reflectivity of the reflective optical element.

10. The method of claim 9, further comprising keeping constant the concentration of the fluorine-containing gas and/or the concentration of the oxygen-containing gas when the control parameter is between a threshold value and an upper threshold value.

11. The method of claim 9, further comprising:
increasing the concentration of the fluorine-containing gas and/or reducing the concentration of the oxygen-containing gas when the control parameter is below the lower threshold value; and/or
reducing the concentration of the fluorine-containing gas and/or increasing the concentration when the control parameter exceeds the upper threshold value.

12. The method of claim 7, wherein, after changing the concentration of the fluorine-containing gas and/or of the oxygen-containing gas, operating the optical system under constant ambient condition for a predefined hold time.

13. The method of claim 9, wherein the control parameter comprises a member selected from the group consisting of a total transmission of the optical system, a reflectivity of the reflective optical element, a chemical composition of the surface of the optical element, and a temperature of the optical element.

14. An optical system, comprising:
a reflective optical element comprising a metallic surface supporting a metal fluoride layer; and
a light source configured to irradiate the reflective optical element with radiation,
wherein:
the optical system is configured to operate under oxidizing ambient conditions of the optical element during a first time interval;
the optical system is configured to operate under fluorinating ambient conditions of the optical element during a second time interval; and
the first time interval follows the second time interval, or the second time interval follows the first time interval.

15. The optical system of claim 14, wherein the optical system is configured to operate under alternately oxidizing ambient conditions of the optical element and fluorinating ambient conditions of the optical element.

16. The optical system of claim 14, wherein:
the reflective optical element is in a chamber;
the optical system comprises a supply device configured to supply a fluorine-containing gas and/or an oxygen-containing gas into the chamber; and
the supply device is configured to set a concentration of the fluorine-containing gas and/or a concentration of the oxygen-containing gas in the chamber.

17. The optical system of claim 14, further comprising:
a control device configured to control the concentration of the fluorine-containing gas and/or of the oxygen-containing gas in the surroundings of the optical element as a function of a control parameter which forms a measure of a reflectivity of the reflective optical element; and
a measuring device configured to measure the control parameter.

18. The optical system of claim 17, wherein the control parameter comprises a member selected from the group consisting of a total transmission of the optical system, a reflectivity of the reflective optical element, a chemical composition of the surface of the optical element, and a temperature of the optical element.

19. The optical system of claim 16, wherein the chamber comprises: an entrance window configured so that radiation from the light source enters the chamber; and/or an exit window configured so that radiation from the light source exits the chamber.

20. The optical system of claim 14, wherein the radiation is in the FUV/VUV wavelength range.
